(19) United States
(12) Patent Application Publication
(10) Pub. No.: US 2010/0213530 A1
(43) Pub. Date: Aug. 26, 2010

(54) Nonvolatile Memory Device and Method of Manufacturing the Same

(75) Inventor: Sang Deok Kim, Suwon-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/650,395

(22) Filed: Dec. 30, 2009

(30) Foreign Application Priority Data
Feb. 23, 2009 (KR) 10-2009-0014683

(51) Int. Cl. H01L 29/788; H01L 21/28

(52) U.S. Cl. 257/316; 438/593; 257/E29.3; 257/E21.209

(57) ABSTRACT

A nonvolatile memory device comprises a gate insulating layer formed on a semiconductor substrate, gate patterns formed on the gate insulating layer, insulating layer spacers defining seams and being coupled together in spaces between the gate patterns, the insulating layer spacers being formed on sidewalls of the gate patterns, a height of the insulating layer spacers being lower than a height of the gate patterns, and an auxiliary layer filling the seams.

### CROSS-REFERENCE TO RELATED APPLICATION

Priority to Korean patent application number 10-2009-0014683 filed on Feb. 23, 2009, the entire disclosure of which is incorporated by reference herein, is claimed.

### BACKGROUND

An embodiment relates generally to a nonvolatile memory device and a method of manufacturing the same and, more particularly, to a nonvolatile memory device and a method of manufacturing the same, which are capable of making gate patterns having uniform shape and characteristics.

The development of nonvolatile flash memory devices, particularly NAND flash memory devices enabling high capacity and high degrees of integration, is actively in progress. The memory cell array of a NAND flash memory device includes strings arranged in a matrix form. Each string structure includes a source select transistor, a drain select transistor, and a number of memory cells coupled in series between the source select transistor and the drain select transistor. Each of the memory cells includes a stack-type gate pattern including a floating gate, a dielectric layer, and a control gate.

Highly-integrated devices such as these are constituted by micro patterns. In line with the micro patterns, there is a need for methods for securing the resistance of a pattern and the characteristic of a device. One of the methods for securing the resistance of a pattern and the characteristic of a device is to use a metal silicide layer having a low resistance at the highest layer of a gate pattern.

A known method of forming gate patterns, each including the metal silicide layer at the highest layer, is described below.

First, a stack layer, including a floating gate, a dielectric layer, and a polysilicon layer, is formed over a semiconductor substrate. A gate hard mask pattern is formed on the polysilicon layer. A first region and a second region are defined in the semiconductor substrate. The first region can correspond to a region in which memory cells are formed, and the second region can correspond to a region in which a source select transistor or a drain select transistor is formed. Next, the stack layer is etched using the gate hard mask pattern as an etch mask, thereby forming stack patterns. In general, the stack pattern is more dense in the first region than in the second region.

Next, an insulating layer spacer is formed on the sidewalls of the stack pattern. Since the stack pattern is more dense in the first region than in the second region, space between the stack patterns in the first region is filled with the insulating layer spacer. On the other hand, since space between the stack patterns in the second region is wider than that in the first region, space between the stack patterns in the second region is not filled with the insulating layer spacer, and neighboring insulating layer spacers in the space between the stack patterns can be isolated from each other. Meanwhile, when the space between the stack patterns formed in the first region is filled with the insulating layer spacer, irregular seams are generated in the space between the stack patterns formed in the first region.

Subsequently, a dielectric interlayer fully fills the space between the stack patterns formed in the second region. Next, polishing and etch processes are performed to expose the polysilicon layer included in the stack patterns. Here, the height of the insulating layer spacer and the dielectric interlayer becomes lower than that of the polysilicon layer such that the sidewalls of the polysilicon layer can be exposed. In the process of performing the etch process for lowering the height of the insulating layer spacer and the dielectric interlayer than that of the polysilicon layer, the seams are exposed and increased in size. Further, the size and shape of the seams become more irregular.

Next, a metal layer is formed on a surface of the dielectric interlayer and the insulating layer spacer including the exposed surface of the polysilicon layer. An annealing process is then performed to form a metal silicide layer through a reaction of the metal layer and polysilicon. Subsequently, the metal layer that remains without reacting to polysilicon is removed to form a control gate (i.e., a stack structure of the polysilicon layer and the metal silicide layer).

A metal silicide layer, such as a cobalt silicide (CoSiₓ) layer, as described above, is formed by depositing a cobalt layer on the exposed surface of the polysilicon layer and diffusing cobalt (Co) into the polysilicon layer through the annealing process. Accordingly, the cobalt layer is not deposited until the polishing and etch processes for exposing the polysilicon layer of the gate patterns are performed.

FIG. 1 is a diagram illustrating the problems in the known method of forming the gate patterns. In particular, FIG. 1 is a diagram showing the gate patterns of the first region.

Referring to FIG. 1, gate patterns each having a stack structure of a floating gate 5, a dielectric layer 7, and a control gate 13 are formed over a semiconductor substrate 1 with a gate insulating layer 3 interposed therebetween. Here, the control gate 13 has a stack structure of a polysilicon layer 9 and a metal silicide layer 11. Meanwhile, the metal silicide layer 11 formed on the polysilicon layer 9 was formed by the method of forming the gate patterns. In accordance with the method of forming the gate patterns, in the process of performing the etch process for lowering the height of insulating layer spacers 15 formed in the second region in order to form the metal silicide layers 11, seams 17 are exposed and increased in size. Further, the size and shape of the seams 17 become more irregular.

With an increase in the size of the seams 17, the metal silicide layers 11 are inclined or collapsed, thereby damaging the topologies of the metal silicide layers 11. Further, with an increase in the irregularity of the seams 17, the degree of damage to the topologies of the metal silicide layers 11 becomes irregular, and the topologies of the metal silicide layers 11 becomes irregular. Moreover, with an increase in the irregularity of the seams 17, the shape of the metal silicide layers 11 becomes irregular. This leads to irregularities in capacitance values between the gate patterns, resulting in an irregular interference phenomenon between the gate patterns, in turn leading to an imbalance in characteristics of nonvolatile memory devices.

### BRIEF SUMMARY

An embodiment relates to a nonvolatile memory device and a method of manufacturing the same, which are capable of producing uniformly-shaped gate patterns and uniform characteristics of devices even though a metal silicide layer is used to lower resistance.

A nonvolatile memory device according to an aspect of this disclosure comprises a gate insulating layer formed on a semiconductor substrate, gate patterns formed on the gate insulating layer, insulating layer spacers defining respective seams formed on sidewalls of the gate patterns and being coupled together in spaces between the gate patterns, a height of the insulating layer spacers being lower than a height of the gate patterns, and an auxiliary layer formed to fill the seams.

Each of the gate patterns preferably comprises a stack pattern having a stack structure of a floating gate, a dielectric layer, and a polysilicon layer, and a cobalt silicide layer formed on the polysilicon layer.

The insulating layer spacer and the auxiliary layer preferably comprise a same material.

The insulating layer spacers and the auxiliary layer preferably comprise an oxide layer.

A method of manufacturing a nonvolatile memory device according to an aspect of this disclosure comprises forming a gate insulating layer on a semiconductor substrate, forming stack patterns on the gate insulating layer, each stack pattern comprising a polysilicon layer, forming insulating layer on sidewalls of the stack patterns, the insulating layer defining seams and being coupled together in a space between the stack patterns, forming insulating layer spacers by etching the insulating layer and lowering a height of the insulating layer spacers to expose sidewalls of the polysilicon layer and to widen opening portions of the seams, and forming an auxiliary layer on a surface of the polysilicon layer and a surface of the insulating layer spacers to fill the seams.

The method preferably further comprises etching the auxiliary layer to expose the surface of the polysilicon layer, and forming a metal silicide layer on the polysilicon layer by reacting the polysilicon layer and a metal.

The metal silicide layer preferably comprises a cobalt silicide layer.

Etching the auxiliary layer to expose the surface of the polysilicon layer preferably is performed by a wet etch process using a buffered oxide etchant (BOE) or a hydrofluoric acid (HF) solution.

The insulating layer spacer and the auxiliary layer preferably comprise a same material.

The insulating layer spacers and the auxiliary layer preferably comprise oxide layers.

The oxide layer preferably is formed using a low pressure-chemical vapor deposition (LP-CVD) method.

Preferably, the stack patterns each comprises the polysilicon layer, and a floating gate and a dielectric layer stacked under the polysilicon layer.

A method of manufacturing a nonvolatile memory device according to another aspect of this disclosure comprises forming a gate insulating layer on a semiconductor substrate, forming stack patterns on the gate insulating layer, each stack pattern comprising a polysilicon layer, the stack patterns defining sidewalls and being spaced from each other, forming insulating layer spacers on sidewalls of the stack patterns, the insulating layer spacers defining seams and having a height lower than a height of the polysilicon layer, the insulating layer spacers being coupled together in spaces between the stack patterns, and forming an auxiliary layer on a surface of the polysilicon layer and a surface of the insulating layer spacers to fill the seams.

The method further comprises etching the auxiliary layer to expose a surface of the polysilicon layer, and forming a metal silicide layer on the polysilicon layer by reacting the polysilicon layer and a metal.

The metal silicide layer comprises a cobalt silicide layer.

The method comprises etching the auxiliary layer to expose the surface of the polysilicon layer by a wet etch process using a buffered oxide etchant (BOE) or a hydrofluoric acid (HF) solution.

The insulating layer spacer and the auxiliary layer comprise a same material.

The insulating layer spacers and the auxiliary layer comprise oxide layers.

The method comprises forming the oxide layer using a low pressure-chemical vapor deposition (LP-CVD) method.

The stack patterns each comprise the polysilicon layer, and a floating gate and a dielectric layer stacked under the polysilicon layer.

### BRIEF DESCRIPTION OF THE DRAWINGS

FIG. 1 is a diagram illustrating problems in a known method of forming gate patterns of a nonvolatile memory device; and FIGS. 2A to 2F are cross-sectional views illustrating a method of manufacturing a nonvolatile memory device according to an embodiment of this disclosure.

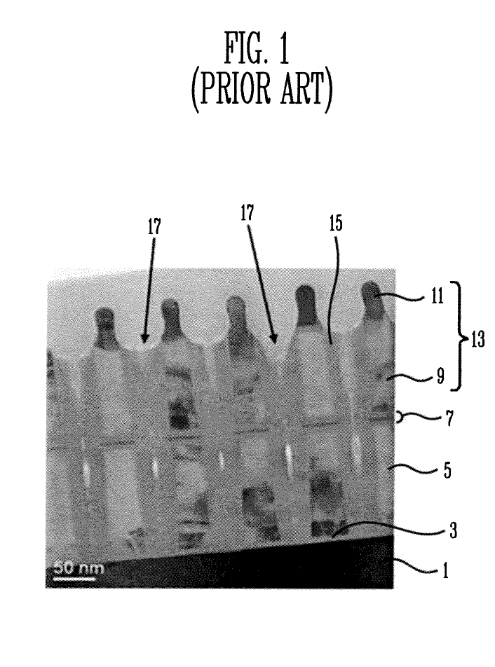

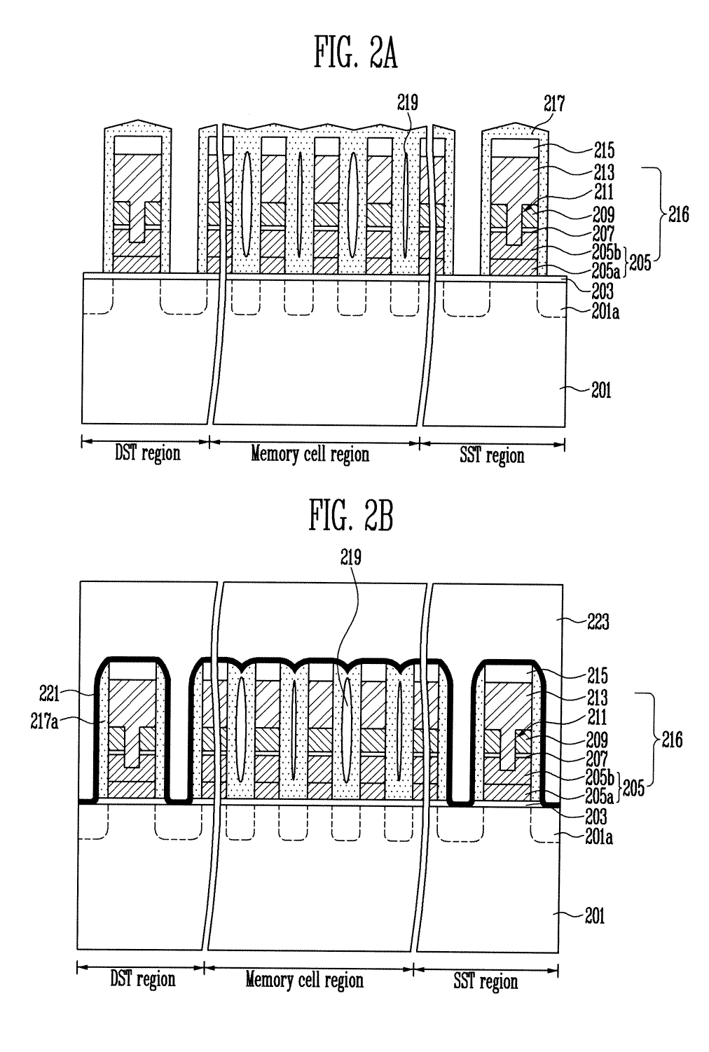

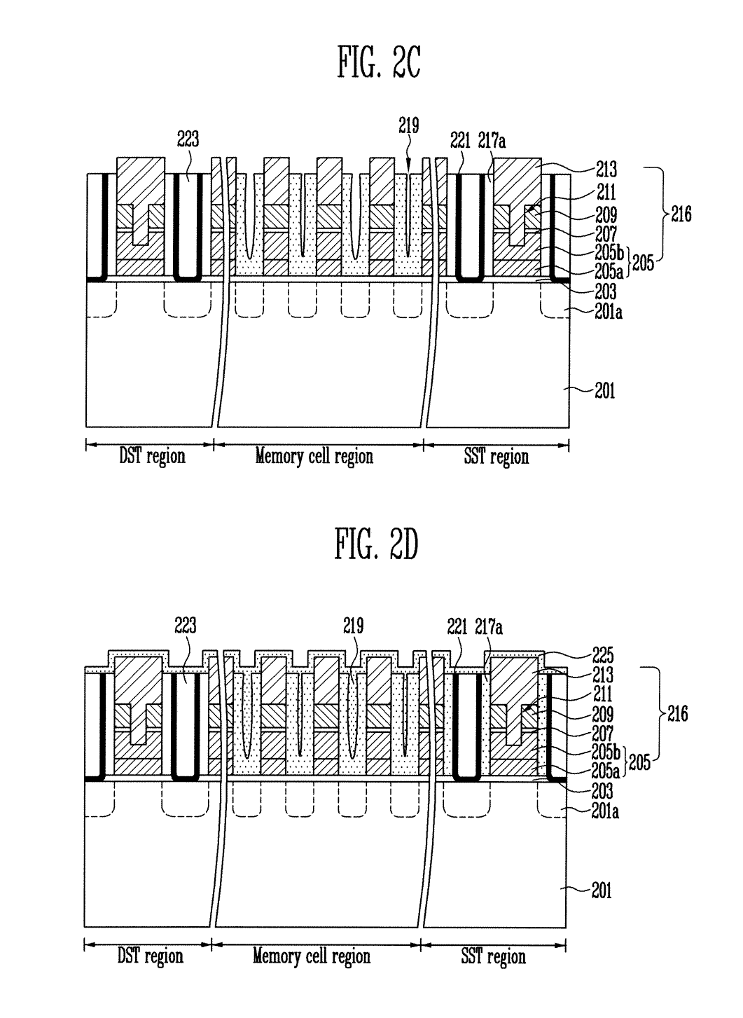

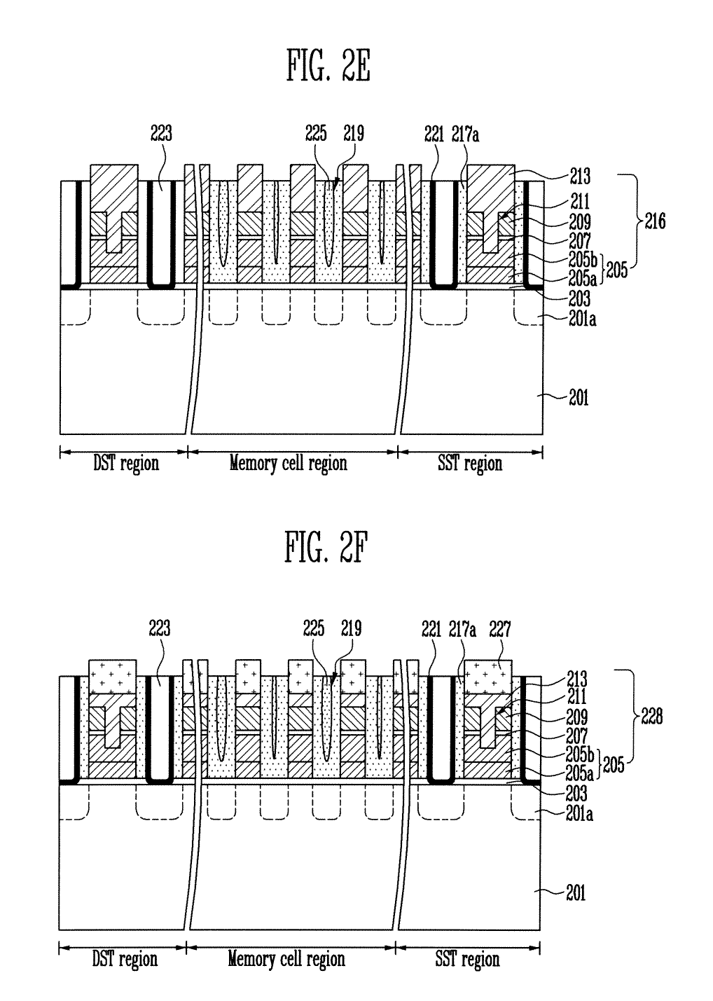

### DESCRIPTION OF EMBODIMENT

An embodiment of the present disclosure is described in detail below with reference to the accompanying drawings. The drawing figures are provided to allow those having ordinary skill in the art to understand the scope of the embodiment of the disclosure.

FIGS. 2A to 2F are cross-sectional views illustrating a method of manufacturing a nonvolatile memory device according to an embodiment of this disclosure.

Referring to FIG. 2A, a well (not shown) is formed, and a gate insulating layer 203 is formed on a semiconductor substrate 201 on which an ion implantation process for controlling the threshold voltage has been performed. Stack patterns 216 in each of which a floating gate 205, a dielectric layer 207, a first polysilicon layer 209 for a capping layer, and a second polysilicon layer 213 for a control gate are stacked are formed on the gate insulating layer 203.

A first region and a second region are defined in the semiconductor substrate 201. The first region preferably is a memory cell region in which memory cells will be formed, and the second region preferably is a drain select transistor (DST) region in which a DST will be formed or a source select transistor (SST) region in which a SST will be formed.

The gate insulating layer 203 preferably comprises an oxide layer and preferably is formed using an oxidization process. The gate insulating layer 203 formed using the oxidization process preferably comprises silicon dioxide (SiO₂).

The stack pattern 216 preferably is more densely formed in the first region (i.e., the memory cell region) than in the second region (i.e., the DST region or the SST region). Thus, an interval between the stack patterns 216 is narrower in the first region than in the second region.

An example of a process of forming the stack patterns 216 is described in detail below. First, a conductive layer for forming the floating gate 205 is formed on the gate insulating layer 203. The conductive layer for forming the floating gate 205 preferably is a stack layer of an undoped polysilicon layer 205a and a doped polysilicon layer 205b or a single layer of a doped polysilicon layer.

An isolation hard mask pattern (not shown) is formed on the conductive layers 205a, 205b. The conductive layers 205a, 205b, the gate insulating layer 203, and the semiconductor substrate 201 are etched using the isolation hard mask pattern as an etch barrier, thereby forming trenches (not shown) in the semiconductor substrate 201.

The trenches are filled with an insulating material to form isolation layers (not shown). Regions of the semiconductor substrate 201 in which the isolation layers are not formed are defined as active regions. Consequently, the gate insulating layer 203 and the conductive layers 205a, 205b remain only on the active regions.

After the isolation layers are formed, the isolation hard mask pattern is removed. The dielectric layer 207 is formed on a surface of the remaining conductive layers 205a, 205b. Here, contact holes 211 to expose the underlying conductive layer 205b are formed in the dielectric layer 207 formed in the second region (i.e., the DST region, the SST region). The dielectric layer 207 preferably has an ONO structure in which an oxide layer, a nitride layer, and an oxide layer are stacked.

When forming the contact holes 211, the first polysilicon layer 209 can be used as an etch barrier in order to prevent the dielectric layer 207, formed in the first region (i.e., the memory cell region), from being damaged. Thus, to form the contact holes 211, the dielectric layer 207 and the first polysilicon layer 209 are stacked on a surface of the conductive layers 205a, 205b. The first polysilicon layer 209 is then patterned. The dielectric layer 207 is etched by an etch process using the patterned first polysilicon layer 209 as an etch barrier to form the contact holes 211. The remaining first polysilicon layer 209 preferably is used as an underlying conductive layer of a control gate. After forming the contact holes 211, the second polysilicon layer 213 is formed on the first polysilicon layer 209. The second polysilicon layer 213 is electrically coupled with the conductive layer 205b through the contact hole 211.

Next, a gate hard mask pattern 215 is formed on the second polysilicon layer 213. The gate hard mask pattern 215 preferably is formed of an oxide layer or, in another preferred embodiment, may be formed of a stack structure of a nitride layer and an oxide layer.

The second polysilicon layer 213, the first polysilicon layer 209, the dielectric layer 207, and the conductive layers 205a, 205b are etched using the gate hard mask pattern 215 as an etch barrier until the gate insulating layer 203 is exposed. Thus, the stack patterns 216 each having the stack structure of the floating gate 205, the dielectric layer 207, the first polysilicon layer 209, and the second polysilicon layer 213 are formed. Here, the floating gates 205 are the results of separating the conductive layers 205a, 205b, remaining on the active regions, into a number of patterns through an etch process using the gate hard mask pattern 215 as an etch barrier.

After the stack patterns 216 are formed as described above, impurity ions are implanted using the stack patterns 216 as a mask to form a junction 201a in the semiconductor substrate 201 between the stack patterns 216.

After forming the junctions 201a, an insulating layer 217 is formed on a surface of the stack patterns 216 and on the gate insulating layer 103. The insulating layer 217 preferably is formed using a low pressure-chemical vapor deposition (LP-CVD) method with excellent step coverage characteristics.

Meanwhile, since the stack pattern 216 is more densely formed in the first region (i.e., the memory cell region) than in the second region (i.e., the DST region, the SST region), the insulating layer 217 can fill the space between the stack patterns 216 formed in the first region (i.e., the memory cell region). In other words, in the first region (i.e., the memory cell region), the insulating layers 217 formed on the sidewalls of each of the stack patterns 216 and configured to neighbor each other are interconnected. Here, in the first region (i.e., the memory cell region), irregular seams 219 are generated in the insulating layers 217 each filling the space between the stack patterns 216.

On the other hand, since the space between the stack patterns 216 in the second region (i.e., the DST region, the SST region), is wider that in the first region (i.e., the memory cell region), the space between the stack patterns 216 in the second region (i.e., the DST region, the SST region) is not filled with the insulating layer 217. Thus, the insulating layers 217 each formed on the sidewalls of each of the stack patterns 216 and neighboring each other in the second region (i.e., the DST region, the SST region) are isolated from each other.

After forming the insulating layers 217, the insulating layers 217 are etched, preferably using an etch-back method.

Referring to FIG. 2B, the insulating layers 217 are etched using an etch-back method until the gate hard mask patterns 215 are exposed to form an insulating layer spacer 217a formed on the sidewalls of each of the stack patterns 216. Here, in the first region (i.e., the memory cell region), the insulating layer spacers 217a formed on the sidewalls of the stack patterns 216 and neighboring each other in the space between the stack patterns 216 are interconnected and include the respective seams 219. Accordingly, the junctions 201a between the stack patterns 216 neighboring each other in the first region (i.e., the memory cell region) are fully covered with the respective insulating layer spacers 217a. On the other hand, the insulating layer spacers 217a formed on the sidewalls of each of the stack patterns 216 in the second region (i.e., the DST region, the SST region) and neighboring each other in the spaces between the stack patterns 216 are isolated from each other. Furthermore, the gate insulating layer 203 not covered with the insulating layer spacer 217a in the second region (i.e., the DST region, the SST region) can be etched by the etch-back process. Accordingly, the junction 201a between the stack patterns 216 neighboring each other in the second region (i.e., the DST region, the SST region) can be exposed. The insulating layer spacer 217a can be formed to a thickness of 300 Å to 1500 Å.

After forming the insulating layer spacers 217a, an etch-stop layer 221 is formed on the exposed surface of the stack patterns 216, the insulating layer spacers 217a, and the junctions 201a. The etch-stop layer 221 is formed to prevent the gate patterns from being exposed in a subsequent etch process for forming a source contact hole or a drain contact hole to expose the junctions 201a. Here, the etch-stop layer 221 comprises a nitride layer.

A dielectric interlayer 223 is formed over the etch-stop layer 221 to a thickness sufficient to fill the spaces between the stack patterns 216 formed in the second region (i.e., the DST region, the SST region). The dielectric interlayer 223 preferably comprises an oxide layer.

Referring to FIG. 2C, a surface of the second polysilicon layer 213 is exposed such that a metal layer deposited in a subsequent process comes into contact with the second polysilicon layer 213. Here, to increase the contact area of the metal layer and the second polysilicon layer 213, the height of the dielectric interlayers 223, the etch-stop layers 221, and the insulating layer spacers 217a is made lower than a height of the second polysilicon layer 213. Accordingly, the top surface and sidewalls of the second polysilicon layer 213 are exposed.

The process of exposing the top surface and sidewalls of the second polysilicon layer 213 preferably comprises a polishing process and an etch-back process. The polishing process preferably is a chemical mechanical polishing (CMP) process. Next, the height of the dielectric interlayers 223, the etch-stop layers 221, and the insulating layer spacers 217a is lowered using the etch-back process. When the height of the dielectric interlayers 223, the etch-stop layers 221, and the insulating layer spacers 217a is lowered using the etch-back process, the seams 219 of the first region are exposed, the opening portions of the seams 219 are further widened, and the uniformity of the seams 219 is further lowered. The exposed seams 219 preferably each has a “V” shape. When the opening portions of the seams 219 are widened using the process of lowering the height of the insulating layer spacers 217a, the degree of burial of the seams 219 can be improved through an auxiliary layer 225 formed in a subsequent process.

Referring to FIG. 2D, the auxiliary layer 225 is formed on the exposed surface of the second polysilicon layers 213 and the surface of the dielectric interlayers 223, the etch-stop layers 221, the insulating layer spacers 217a to fill the seams 219.

The auxiliary layer 225 preferably is formed using an LP-CVD method with excellent step coverage characteristics such that the auxiliary layer 225 is formed along the step between the exposed surface of the second polysilicon layers 213 and the surface of the dielectric interlayers 223, the etch-stop layers 221, the insulating layer spacers 217a. Further, the auxiliary layer 225 preferably is formed to a thickness of 50 Å to 200 Å such that the seams 219 are filled.

The auxiliary layer 225 preferably comprises the same material as the material of the insulating layer spacers 217a such that the auxiliary layer 225 is etched simultaneously with the insulating layer spacers 217a in a subsequent etch process. Furthermore, when the auxiliary layer 225 and the insulating layer spacers 217a comprise the same material, materials formed in the space between the stack patterns 216 in the first region (i.e., the memory cell region) are identical with each other. Thus, although the seams 219 are irregularly formed between the stack patterns 216 of the first region (i.e., the memory cell region), the dielectric constant of an insulating layer formed between the stack patterns 216 of the first region (i.e., the memory cell region) can become regular because the auxiliary layers 225 and the insulating layer spacers 217a are filled with the same material.

The insulating layer spacers 217a and the auxiliary layer 225 preferably comprise an oxide layer although they can comprise a nitride layer. In this case, since the dielectric constant of the nitride layer is higher than that of the oxide layer, an interference phenomenon between the gate patterns can be increased.

Referring to FIG. 2E, the auxiliary layer 225 is etched to expose the surfaces of the second polysilicon layers 213. Here, the auxiliary layer 225 preferably is etched such that the top surface and sidewalls of the second polysilicon layers 213 are exposed.

The auxiliary layer 225 preferably is etched using an etch-back method. Further, the auxiliary layer 225 and the insulating layer spacers 217a preferably are etched with the same etch selectivity because the insulating layer spacers 217a and the auxiliary layer 225 are made of the same material. Accordingly, the auxiliary layer 225 and the insulating layer spacers 217a can be etched at the same time, but the seams 219 are not opened.

Meanwhile, the auxiliary layer 225 preferably is etched using material having a high etch selectivity for the auxiliary layer 225 to the second polysilicon 213. To this end, the auxiliary layer 225 formed of the oxide layer preferably is etched by a wet etch process using a buffered oxide etchant (BOE) or a hydrofluoric acid (HF) solution. Further, the auxiliary layer 225 preferably is etched using the thickness of 50 Å to 250 Å as a target such that the top and sidewalls of the second polysilicon layer 213 are exposed.

Referring to FIG. 2F, the exposed second polysilicon layers 213 is reacted with metal, thereby forming metal silicide layers 227 on the respective second polysilicon layers 213. Accordingly, the gate patterns 228 each having the stack structure of the floating gate 205, the dielectric layer 207, the polysilicon layers 209, 213, and the metal silicide layer 227 are formed.

Hereinafter, an example of a method of forming the gate pattern 228 including the metal silicide layer 227 is described in detail below.

First, a metal layer (not shown) and an anti-oxidization layer (not shown) are stacked over the exposed surfaces of the second polysilicon layers 213. The metal layer is deposited to form the metal silicide layers 227 through a reaction with the second polysilicon layers 213 in a subsequent process. The metal layer preferably comprises cobalt (Co). The anti-oxidization layer prevents a surface of the metal layer from being oxidized in a subsequent process of performing an annealing process such that the metal layer can react with the second polysilicon layers 213 in a subsequent process. The anti-oxidization layer preferably is formed by stacking a titanium (Ti) layer and a titanium nitride (TiN) layer.

Next, an annealing process is performed such that the metal layer and the second polysilicon layers 213 react with each other. After the annealing process, the top surfaces of the second polysilicon layers 213 react to the metal layer, thereby forming the metal silicide layers 227 on the respective second polysilicon layers 213. The metal silicide layers 227 formed using the cobalt layer as the metal layer are cobalt silicide layers. The annealing process for forming the metal silicide layer 227 can be classified into a first annealing process and a second annealing process. For example, a case where the cobalt silicide layer is formed is described below. The first annealing process is performed at a first temperature to form the cobalt silicide layer on CoSi. Next, the second annealing process is performed at a second temperature higher than the first temperature to thereby change the phase of the cobalt silicide layer on the CoSi into the cobalt silicide layer on CoSi₂. The cobalt silicide layer on the CoSi₂ is more stable than the cobalt silicide layer on the CoSi and has a low resistance.

After forming the metal silicide layers 227, the metal layer and the anti-oxidization layer that remain without reacting are removed using a strip process. Accordingly, the gate patterns 228 each comprising the metal silicide layer 227 for low-resistance wiring can be formed.

As described above, according to the disclosure, the opening portions of the seams formed in the respective insulating layer spacers are widened using the process of lowering the height of the insulating layer spacers, and the auxiliary layer is then formed. Accordingly, the degree of burial of the seams can be improved although the auxiliary layer made of material having a low coating ability.

Furthermore, according to the disclosure, the seams are filled with the auxiliary layer made of the same material as the insulating layer spacers. Accordingly, capacitance and an interference phenomenon between the gate patterns can become uniform.

Furthermore, according to the disclosure, since the seams are filled with the auxiliary layer, a failure, such as irregularity in the form of the gate patterns resulting from the seams, can be improved.

Further, according to the disclosure, since capacitance between the gate patterns becomes uniform and the shape of the gate patterns can become uniform. Accordingly, the characteristics of nonvolatile memory devices can become uniform and reliability of nonvolatile memory devices can be improved.

What is claimed is:

1. A nonvolatile memory device, comprising:
a gate insulating layer formed on a semiconductor substrate;
gate patterns formed on the gate insulating layer, said gate patterns defining sidewalls and being spaced from each other;
insulating layer spacers defining respective seams and coupled together in spaces between the gate patterns, said insulating layer spacers being formed on sidewalls of the gate patterns, a height of the insulating layer spacers being lower than a height of the gate patterns; and
an auxiliary layer filling the seams.

2. The nonvolatile memory device of claim 1, wherein each of the gate patterns comprises a stack pattern having a stack structure of a floating gate, a dielectric layer, a polysilicon layer, and a cobalt silicide layer formed on the polysilicon layer.

3. The nonvolatile memory device of claim 1, wherein the insulating layer spacer and the auxiliary layer comprise a same material.

4. The nonvolatile memory device of claim 1, wherein the insulating layer spacers and the auxiliary layer each comprise an oxide layer.

5. A method of manufacturing a nonvolatile memory device, comprising:
forming a gate insulating layer on a semiconductor substrate;
forming stack patterns on the gate insulating layer, each stack pattern comprising a polysilicon layer and defining sidewalls, the stack patterns being spaced from each other;
forming insulating layer on sidewalls of the stack patterns, the insulating layer defining seams and being coupled together in spaces between the stack patterns;
forming insulating layer spacers by etching the insulating layer and lowering a height of the insulating layer spacers to expose sidewalls of the polysilicon layer and to widen opening portions of the seams; and
forming an auxiliary layer on a surface of the polysilicon layer and a surface of the insulating layer spacers to fill the seams.

6. The method of claim 5, further comprising:
etching the auxiliary layer to expose a surface of the polysilicon layer; and
forming a metal silicide layer on the polysilicon layer by reacting the polysilicon layer and a metal.

7. The method of claim 6, wherein the metal silicide layer comprises a cobalt silicide layer.

8. The method of claim 6, comprising etching the auxiliary layer to expose the surface of the polysilicon layer by a wet etch process using a buffered oxide etchant (BOE) or a hydrofluoric acid (HF) solution.

9. The method of claim 5, wherein the insulating layer spacer and the auxiliary layer comprise a same material.

10. The method of claim 5, wherein the insulating layer spacers and the auxiliary layer comprise oxide layers.

11. The method of claim 10, comprising forming the oxide layer using a low pressure-chemical vapor deposition (LP-CVD) method.

12. The method of claim 5, wherein the stack patterns each comprise the polysilicon layer and a floating gate and a dielectric layer stacked under the polysilicon layer.

13. A method of manufacturing a nonvolatile memory device, comprising:
forming a gate insulating layer on a semiconductor substrate;
forming stack patterns on the gate insulating layer, each stack pattern comprising a polysilicon layer, the stack patterns defining sidewalls and being spaced from each other;
forming insulating layer spacers on sidewalls of the stack patterns, the insulating layer spacers defining seams and having a height lower than a height of the polysilicon layer, the insulating layer spacers being coupled together in spaces between the stack patterns; and
forming an auxiliary layer on a surface of the polysilicon layer and a surface of the insulating layer spacers to fill the seams.

14. The method of claim 13, further comprising:
etching the auxiliary layer to expose a surface of the polysilicon layer; and
forming a metal silicide layer on the polysilicon layer by reacting the polysilicon layer and a metal.

15. The method of claim 14, wherein the metal silicide layer comprises a cobalt silicide layer.

16. The method of claim 14, comprising etching the auxiliary layer to expose the surface of the polysilicon layer by a wet etch process using a buffered oxide etchant (BOE) or a hydrofluoric acid (HF) solution.

17. The method of claim 1, wherein the insulating layer spacer and the auxiliary layer comprise a same material.

18. The method of claim 13, wherein the insulating layer spacers and the auxiliary layer comprise oxide layers.

19. The method of claim 18, comprising forming the oxide layer using a low pressure-chemical vapor deposition (LP-CVD) method.

20. The method of claim 13, wherein the stack patterns each comprise the polysilicon layer, and a floating gate and a dielectric layer stacked under the polysilicon layer.
